(19) United States
(12) Patent Application Publication
(10) Pub. No.: US 2025/0107354 A1
(43) Pub. Date: Mar. 27, 2025

(54) DISPLAY APPARATUS HAVING IMPROVED APERTURE RATIO

(71) Applicant: LG Display Co., Ltd., Seoul (KR)

(72) Inventor: Joon-Young HEO, Paju-si (KR)

(21) Appl. No.: 18/886,684

(22) Filed: Sep. 16, 2024

(30) Foreign Application Priority Data
Sep. 25, 2023 (KR) 10-2023-0127975

(51) Int. Cl. H10K 59/123; H10K 59/12

(52) U.S. Cl. CPC H10K 59/123; H10K 59/1201

(57) ABSTRACT

A display apparatus according to the present disclosure includes a substrate including a plurality of sub-pixels, a transistor disposed in each sub-pixel, a first planarization layer formed in the entire area of the substrate to cover the transistor, a light emitting device disposed in each sub-pixel, the light emitting device being electrically connected to the transistor through an contact hole formed in the first planarization layer; and a step prevention member formed in a predetermined region including the first contact hole in each sub-pixel.

### CROSS-REFERENCE TO RELATED APPLICATIONS

This application claims priority to Korean Patent Application No. 10-2023-0127975, filed in the Republic of Korea on Sep. 25, 2023, the entire contents of which is hereby expressly incorporated by reference into the present application.

### BACKGROUND

### Technical Field

The present disclosure relates to a display apparatus having improved aperture ratio.

### Description of the Related Art

Recently, the importance of display apparatus has increased with the development of multimedia. Various display apparatus, such as liquid crystal display and organic light emitting displays, have been proposed. Among these display apparatus, an organic light emitting display apparatus is currently widely used because of a high response speed, high brightness, and a good viewing angle.

However, in the case of the organic light emitting display apparatus for displaying the images using R (Red), G (Green), and B (Blue) light emitting devices, there was a problem that the aperture ratio was small. In particular, there was a problem of a decrease in aperture ratio due to the bank layer that partitions the R, G, and B light emitting devices.

### BRIEF SUMMARY

An object of the present disclosure is to provide a display apparatus having improved aperture ratio.

In order to achieve the object, a display apparatus according to the present disclosure comprises a substrate including a plurality of sub-pixels, a transistor disposed in each sub-pixel, a first planarization layer formed in the entire area of the substrate to cover the transistor, a light emitting device disposed in each sub-pixel, the light emitting device being electrically connected to the transistor through an contact hole formed in the first planarization layer; and a step prevention member formed in a selected region including the first contact hole in each sub-pixel.

The step prevention member may be extended to an upper surface of the first planarization layer from an inside of the first contact hole. At this time the light emitting device can include a first electrode disposed on the first planarization layer and in the inside of the first contact hole in each sub-pixel, a light emitting layer disposed in side and upper surfaces of the step prevention layer and on the upper surface of the first electrode, and a second electrode disposed on the light emitting layer.

The step prevention member can be filled only within the inside of the first contact hole. At this time, the light emitting device can include a first electrode disposed on the first planarization layer and in the inside of the first contact hole in each sub-pixel, a light emitting layer disposed on the upper surface of the step prevention layer and on the upper surface of the first electrode, and a second electrode disposed on the light emitting layer.

The light emitting layer formed on the upper surface of the step prevention member and the light emitting layer formed on the upper surface of the first electrode may be at the same level.

The step prevention member may be disposed in a region where the transistor is formed and the step prevention member may be disposed in a boundary region of the plurality of sub-pixels.

The step prevention member may be made of at least one material selected from a group consisting of an inorganic insulating material, an organic insulating material, and a photosensitive agent having a black pigment.

A protective layer may be disposed on the upper surface of the second electrode in each sub-pixel, a second planarization layer may be formed in the entire area of the substrate, and a connecting electrode connected electrically to the second electrodes of the plurality of light emitting devices may be disposed on the second planarization layer.

The second planarization layer may be formed at the same level as the second electrode to expose the second electrode to the outside on the surface of the second planarization layer so that the connecting electrode may be electrically connected to the exposed second electrode.

The second electrode may be covered with the second planarization layer having a second contact hole thereon so that the connecting electrode may be electrically connected to the second electrode through the second contact hole.

A method of fabricating a display apparatus according to the present disclosure comprises providing a substrate including a plurality of sub-pixels, forming a transistor in each sub-pixels, forming a first planarization layer in entire area of the substrate and etching the first planarization layer over the transistor to form a first contact hole, forming a first electrode in an inside of the first contact hole in each sub-pixel and on the first planarization layer, forming a step prevention member in a selected portion including the first contact hole, depositing a material having orthogonality and a photo resist in the entire area of the substrate, developing the photo resist to form a second pattern, over-etching the material having orthogonality using the second pattern to form a first pattern to form an undercut shape with the second pattern, depositing a light emitting material and a conductive material using the first pattern and the second pattern in the undercut shape as a mask layer to form a light emitting layer and a second electrode, and removing the first pattern and the second pattern by a lift-off process.

A protective layer is formed over the second electrode using the first pattern and the second pattern in the undercut shape as the mask layer, a second planarization layer is formed in the entire area of the substrate, and a connecting electrode connected electrically to the light emitting device is formed on the second planarization layer.

The second electrode is exposed to outside through the surface of the second planarization layer by etching the entire area of second planarization layer in selected thickness, and the connecting electrode is electrically connected to the exposed upper surface of the second electrode.

A second contact hole is formed by etching the second planarization layer over the second electrode, and the connecting electrode is electrically connected to the second electrode through the second contact hole.

### BRIEF DESCRIPTION OF THE SEVERAL VIEWS OF THE DRAWINGS

FIG. 1 is a schematic block diagram of an organic light emitting display apparatus according to the present disclosure.

FIG. 2 is a schematic block diagram of a sub-pixel of the organic light emitting display apparatus according to the present disclosure.

FIG. 3 is the circuit diagram conceptually showing the sub-pixel of the display apparatus according to the present disclosure.

FIG. 4 is a plan view schematically showing a sub-pixel of the display apparatus according to the first embodiment of the present specification.

FIG. 5 is a plan view schematically showing the sub-pixel of the display apparatus with a general structure.

FIG. 6 is a cross-sectional view showing the structure of the sub-pixel of the display apparatus according to the first embodiment of the present specification.

FIGS. 7A to 7J are views showing a method of manufacturing the display apparatus according to a first embodiment of the present disclosure.

FIG. 8 is a cross-sectional view showing the structure of the sub-pixel of the display apparatus according to the second embodiment of the present specification.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc., may be used. These terms are only for distinguishing the elements from other elements, and the essence, order, or number of the elements are not limited by the terms. When it is described that a component is “coupled” or “connected” to another component, the component may be directly coupled or connected to the other component, but indirectly without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This disclosure can be applied to the various display apparatus. For example, the display apparatus of this disclosure can be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

Hereinafter, the present disclosure will be described in detail with reference to the attached drawings.

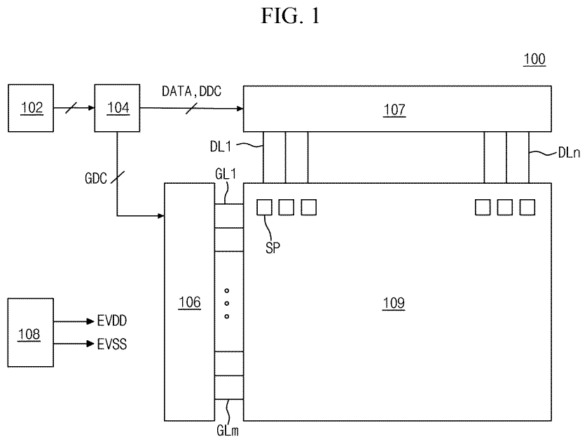

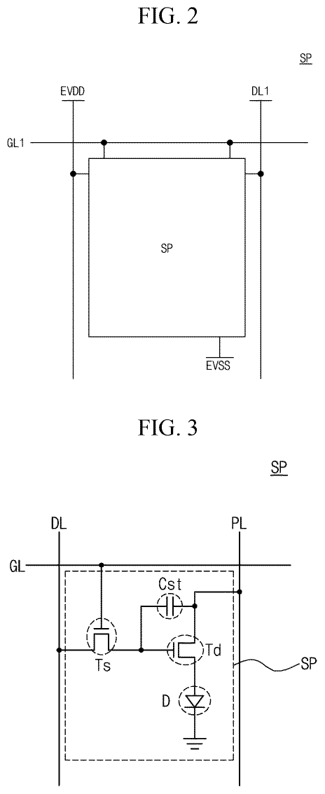

FIG. 1 is the schematic block diagram of a display apparatus 100 according to the present disclosure and FIG. 2 is the schematic block diagram of the sub-pixel SP shown in FIG. 1.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DLI to DLn. In this case, the data driving unit 107 may be mounted on the upper surface of the display panel 109 in the form of an integrated circuit (IC), but is not limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit.

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor DT, a storage capacitor Cst, and a light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the light emitting device D from the power line PL through the driving thin film transistor Td and then the light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

Hereinafter, the structure of the display apparatus according to the present disclosure is specifically described.

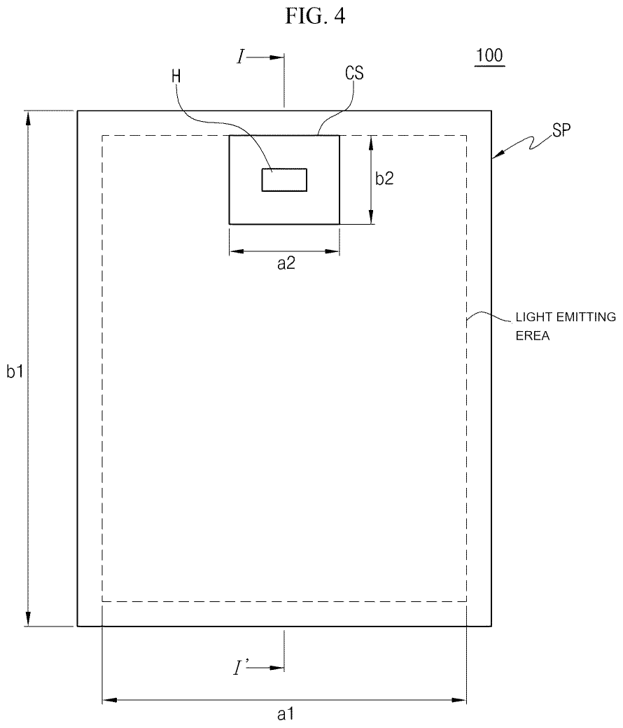

FIG. 4 is a drawing showing the sub-pixel SP of the display apparatus 100 according to the present disclosure.

As shown in FIG. 4, the sub-pixel SP of the display apparatus 100 according to the present disclosure may be formed in an approximately rectangular shape. However, the shape of the sub-pixel SP is not limited to the rectangular shape, and may be formed in various shapes depending on the shape of the electronic product, etc.

Although only one sub-pixel SP is shown in the drawing, in the actual display apparatus 100, a plurality of sub-pixels SP may be arranged in a matrix shape of n×m (where, n and m are natural numbers). For example, the sub-pixel SP may be a green sub-pixel that emits green light, a red sub-pixel that emits red light, and a blue sub-pixel that emits blue light, but is not limited thereto. Further, the sub-pixel SP may be a white sub-pixel that emits white light.

A light emitting device D for emitting the light and a thin film transistor (not shown in the drawing) may be arranged in the sub-pixel SP. For example, the light emitting device D may be the organic light emitting device, but is not limited thereto.

Although not shown in the drawing, the light emitting device D can include a first electrode, a second electrode, and an light emitting layer therebetween. At this time, the light emitting device D is formed for each sub-pixel SP. That is, one light emitting device D is arranged in each sub-pixel SP.

The area where the light emitting device D is formed is the light emitting area where the light is emitted. At this time, since the light emitting layer is formed only in a desired area by the evaporation method, the light emitting device D can be disposed in the region spaced a certain distance inward from the outer edge of the sub-pixel SP. Accordingly, the size S1 of the light emitting area where light is emitted becomes S1=a1×b1.

In the sub-pixel SP, a hole H is formed to electrically connect the thin film transistor and the light emitting device D, and a step prevention member CS is formed inside and around the hole H to prevent the damage of the light emitting layer by the hole H. At this time, the size S2 of the step prevention member CS is S2=a2×b2. Since light is not emitted from the step prevention member CS, the actual size of the light emitting area of the display apparatus 100 according to the present disclosure becomes (a1×b1)−(a2×b2).

As described above, in the display apparatus 100 according to the present disclosure, the light emitting layer of the light emitting device D is formed only in the sub-pixel SP, and the thin film transistor and the light emitting device D are electrically connected by the step prevention member CS, so that the aperture ratio of the display apparatus 100 can be significantly improved. This will be described below.

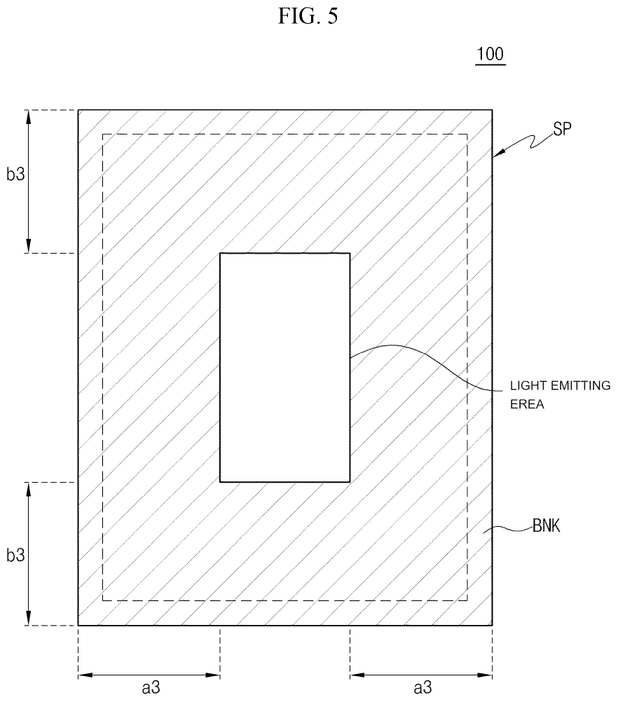

FIG. 5 is a schematic plan view of the organic light emitting display apparatus 100 of a general structure.

As shown in FIG. 5, in the general display apparatus 100, a bank layer BNK is formed around the sub-pixel SP, so that each of the sub-pixels SP is partitioned from each other. In this display apparatus 100, the light emitting layer of the light emitting device D is formed by applying the organic material. Therefore, when applying the organic material, due to the fluidity of the organic material, the organic material of a specific color can be applied not only to the sub-pixel SP of the corresponding color, but also to the sub-pixel SP of a different color. The bank layer BNK is a partition that confines the organic material to the corresponding sub-pixel SP when the light emitting layer is formed, so that the organic material is not applied to the adjacent sub-pixel SP of the different color.

Since the bank layer BNK should be formed with a width greater than the set width to the outside of the sub-pixel SP to prevent the organic material applied when forming the light emitting layer from flowing to the adjacent sub-pixel SP, the bank layer BNK is overlapped with the outer area of the light emitting device D.

Since the bank layer BNK is not the area where light is output, the size of the light emitting area where light is actually output in this display apparatus 100 is the area of the sub-pixel SP (S1) minus the area of the bank layer BNK (2a3×2b3).

That is, in the display apparatus 100 according to the present disclosure, the bank layer is not formed, and only the step prevention member CS is formed within the sub-pixel SP, so that the region of the entire area of the light emitting device D minus the step prevention member CS is the actual light emitting region. On the other hand, in the general display apparatus 200, the region exposed by the bank layer BNK is the actual light emitting region.

In the general display apparatus, the large portion of the sub-pixel SP is blocked by the bank layer BNK, so that the aperture ratio, which is the ratio of the actual light emitting portion to the entire sub-pixel SP, is approximately 30.1%. On the contrary, in the display apparatus 100 according to the present disclosure, the aperture ratio is increased to approximately 60.7%.

As described above, in the display apparatus 100 according to the present disclosure, the light emitting layer of the light emitting device D can be formed only in the corresponding sub-pixel SP without the bank layer BNK by the deposition method, so that the aperture ratio of the display apparatus 100 can be significantly improved.

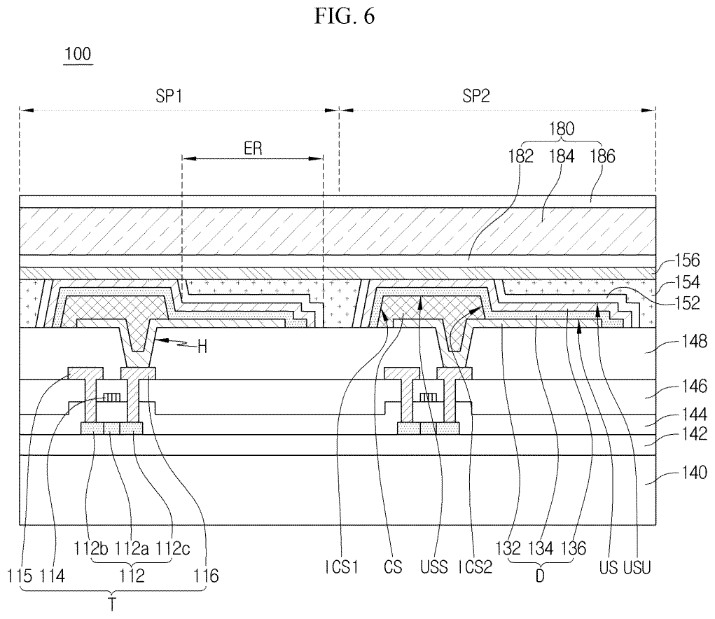

FIG. 6 is a cross-sectional view taken along line I-I′ of FIG. 4 showing the structure of the sub-pixel of the display apparatus 100 according to the first embodiment of the present disclosure. Although a plurality of sub-pixels are actually arranged in the display apparatus 100, only two adjacent sub-pixels SP1, and SP2 are shown in the drawing for convenience of explanation.

As shown in FIG. 6, a buffer layer 142 is formed on a substrate 140. The substrate 140 may be made of a hard material such as a glass or a plastic material, but not limited thereto. For example, the plastic material may include a polyimide, a polymethylmethacrylate, a polyethylene tereththalate, a Polyethersulfone, and a Polycarbonate.

When the substrate 140 is made of polyimide, the substrate 140 may be made of a plurality of polyimide layers, and an inorganic layer may be further disposed between the polyimide layers, but is not limited thereto.

The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is formed on the buffer layer in each sub-pixel SP1, and SP2. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 may be formed in the entire area of the substrate 140 or formed only in a part area of the substrate 140. The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate where the thin film transistor is disposed. The planarization layer 148 may be formed of the organic material such as photoacrylic. But it is not limited thereto. The planarization layer 148 may include a plurality of layers including the inorganic layer and the organic layer.

A light emitting device D is disposed in each sub-pixel SP1 and SP2 on the planarization layer 148. The light emitting device D includes a first electrode 132, an light emitting layer 134, and a second electrode 136.

The first electrode 132 is disposed on the planarization layer 148 and electrically connected to the drain electrode 116 of the thin film transistor through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 110 is a bottom emission type display apparatus, the first electrode 132 may be made of the transparent conductive material such as ITO or IZO.

The step prevention member CS is disposed inside the contact hole H in the first planarization layer 148 and on the first electrode 132 on the first planarization layer 148. The step prevention member CS is filled in to the contact hole H, so that the organic material is not formed inside the contact hole H, and as a result, the light emitting layer 134 is not defective due to the step of the contact hole H. The step prevention member CS is filled into the contact hole H to flatten the area where the light emitting layer 134 is formed, thereby preventing defects in the light emitting layer 134.

The step prevention member CS can be formed to extend outside one end of the first electrode 132 to surround one end of the first electrode 132, but is not limited thereto. Since the size of the step prevention member CS has a significant effect on the aperture ratio of the display apparatus 100, it is desirable to minimize the size of the step prevention member CS.

For example, the step prevention member CS can be disposed over the thin film transistor T with the size similar to that of the thin film transistor T. Since the thin film transistor T can be the portion where light is not emitted, the step prevention member CS can be disposed over the thin film transistor T to minimize the reduction of the light emitting area by the step prevention member CS.

Further, the step prevention member CS can be disposed in the boundary region between the sub-pixels SP1 and SP2. The adjacent sub-pixels SP1 and SP2 output light of different colors. Therefore, when light output from the specific sub-pixel, for example SP1, is incident on the adjacent sub-pixel, for example SP2, the defect due to color mixing may occur. In the present disclosure, the color mixing defect can be prevented by disposing the step prevention member CS in the boundary portion between the sub-pixels SP1 and SP2. In addition, since a part of the step prevention member CS is formed in the boundary region of the sub-pixels SP1 and SP2 where light is not output, the reduction of the size of the light emitting area due to the step prevention member CS can be minimized.

The step prevention member CS can be made of at least one material selected from the group consisting of the inorganic insulating material such as SiNx or SiOx, the organic insulating material such as a BCB (BenzoCycloButene), an acrylic resin, an epoxy resin, a phenolic resin, a polyamide resin, and a polyimide resin, and a photosensitive agent including a black pigment, but is not limited thereto.

The light emitting layer 134 is formed on the upper surface US of the first electrode 132 and the inclined surface (e.g., a first inclined surface ICS1 and a second inclined surface ICS2 facing and opposite of the first inclined surface ICS1) and the upper surface USS of the step prevention member CS. The light emitting layer 134 may be formed in the R, G, and B pixels and may include an R-emitting layer that emits red light, a G-emitting layer that emits green light, and a B-emitting layer that emits blue light. For example, the light emitting layer 134 may include an organic light emitting layer, an inorganic light emitting layer, a nano-sized material layer, a quantum dot, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The light emitting layer 134 may be formed wider than the first electrode 132 to cover the side end of the first electrode 132, but is not limited thereto.

The second electrode 136 is disposed on the light emitting layer 134 and may be formed of the single layer or the multi layers made of the metal or the alloy thereof. Further, the second electrode 136 may be made of the transparent metal oxide material such as ITO or IZO, but is not limited thereto.

When the display apparatus 100 is the top emission type, the second electrode 136 may be made of the half-transparent conductive material that transmits light. For example, the second electrode 188 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the second electrode 136 may be the reflective electrode made of the opaque conductive material. For example, the second electrode 188 may be made of at least one or more of silver (Ag), aluminum (Al), gold (Au), molybdenum (Mo), tungsten (W), chromium (Cr), or alloys thereof.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the light emitting layer doped with an alkali metal such as Li, Na, K, or Cs or an alkaline earth metal such as Mg, Sr, Ba, or Ra, but is not limited thereto.

Like the first electrode 132 and the light emitting layer 134, the second electrode 136 is also formed only within the sub-pixels SP1 and SP2 and is disconnected from the adjacent sub-pixels.

The first electrode 132 of the light emitting device D is disposed under the step prevention member CS, and the light emitting layer 134 and the second electrode 136 are disposed on the side ICS1, ICS2 and upper surface USS of the step prevention member CS, so that the first electrode 132 and the light emitting layer 134 are separated by the step prevention member CS, and as a result, light is not emitted in the portion where the step prevention member CS is disposed.

On the other hand, in portions of the sub-pixels SP1 and SP2 except for the step prevention member CS, the first electrode 132, the light emitting layer 134, and the second electrode 136 are sequentially formed, so that light is emitted in this portion. Therefore, the actual light emitting area ER of the display apparatus 100 according to the present disclosure is the portion where the light emitting device D is disposed, that is, the portion where the first electrode 132, the light emitting layer 134, and the second electrode 136 are formed, minus the portion where light is not emitted by the step prevention member CS.

A protective layer 152 is formed on the upper surface USU of the second electrode 136 formed on the side of the step prevention member CS and the upper surface USU of the second electrode 136 of the actual light emitting area ER except for the upper surface USU of the second electrode 136 over the step prevention member CS. The protective layer 152 is formed to protect the lower light emitting device D from external impacts such as chemicals when forming the light emitting device D. The protective layer 152 may be formed of the single layer of inorganic material such as SiOx or SiNx, but is not limited thereto. This protective layer 152 may be omitted as needed.

A second planarization layer 154 is formed over the entire area of the substrate 140 except for the upper surface of the second electrode 136 over the step prevention member CS. At this time, since the second planarization layer 154 is formed at the same level as the upper surface of the second electrode 136 over the step prevention member CS, the upper surface of the second electrode 136 over the step prevention member CS is exposed to the outside between the second planarization layers 154.

The second flattening layer 154 may be formed of the organic material such as photo acrylic, but is not limited thereto and may be formed the multiple layers including the inorganic layers and the organic layers.

A connecting electrode 156 is formed on the upper surface of the second planarization layer 154 and the upper surface of the second electrode 136 over the step prevention member CS. The connecting electrode 156 is electrically contacted with the second electrode 136 of the sub-pixels SP1 and SP2 exposed to the outside through the second planarization layer 154, so that the second electrodes 136 of all the sub-pixels SP1 and SP2 of the display apparatus 100 are electrically connected by the connecting electrode 156.

In other word, in this disclosure, the light emitting device D is independently disposed in each of the sub-pixels SP1 and SP2, but the second electrodes 136 of the light emitting devices D are electrically connected for each other by the connecting electrode 156, so that the low potential voltage is applied to the entire light emitting devices D by a single signal.

The connecting electrode 156 may be formed of a transparent metal oxide such as ITO or IZO, but is not limited thereto.

An encapsulation layer 180 is formed over the connecting electrode 156. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 180 blocks impurities such as the oxygen and the moisture from the outside to prevent defects of the light emitting device D and various electrodes.

The encapsulation layer 180 may be formed of a first encapsulation layers 182, a second encapsulation layer 184, and a third encapsulation layer 186, but is not limited thereto. The encapsulation layer 180 may be formed of two layers or four or more layers.

The first encapsulation layers 182 and the third encapsulation layer 186 may be made of the inorganic material such as SiOx or SiNx, but are not limited thereto. The second encapsulation layer 184 may be made of the organic insulating material such as acrylic resin, epoxy resin, polyimide, polyethylene, or silicon oxycarbon (SiOC), but is not limited thereto. Further, the third encapsulation layer 186 may be made of thin metal (Face Seal Metal), but is not limited thereto.

Not shown in figure, a touch member may be disposed on the encapsulating layer 180. The touch member can detect external touch information using the user's finger or a touch pen.

As described above, in the display apparatus 100 according to the present disclosure, since the bank layer that divides the sub-pixels SP1 and SP2 and overlaps the light emitting device is not disposed, the aperture ratio can be significantly improved.

Further, in the present disclosure, since the step prevention member CS is filled in the contact hole H formed in the first planarization layer 148 over the thin film transistor, the defects caused by the contact hole H can be prevented.

Hereinafter, the manufacturing method of the display apparatus 100 according to the first embodiment of the present disclosure will be described in detail.

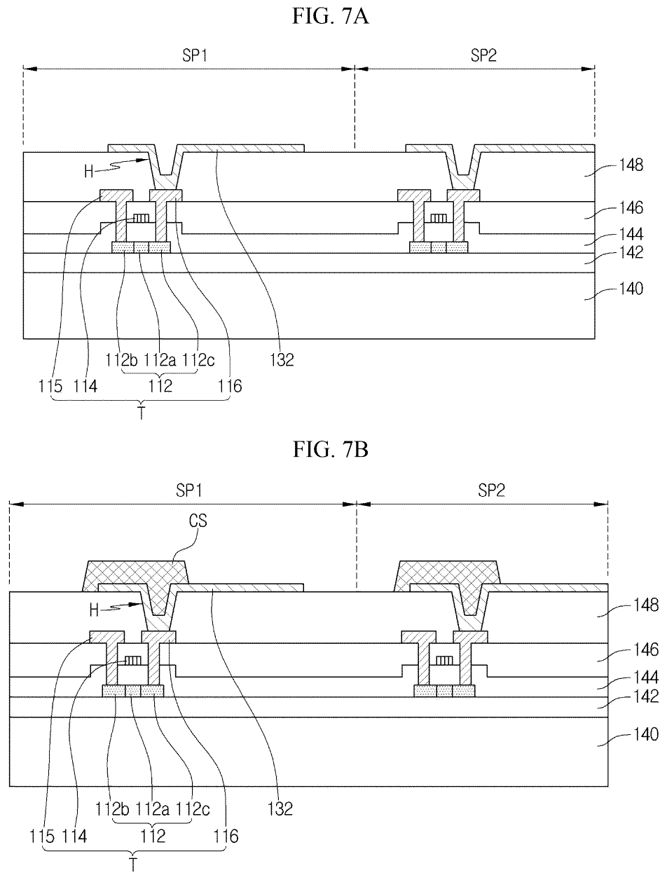

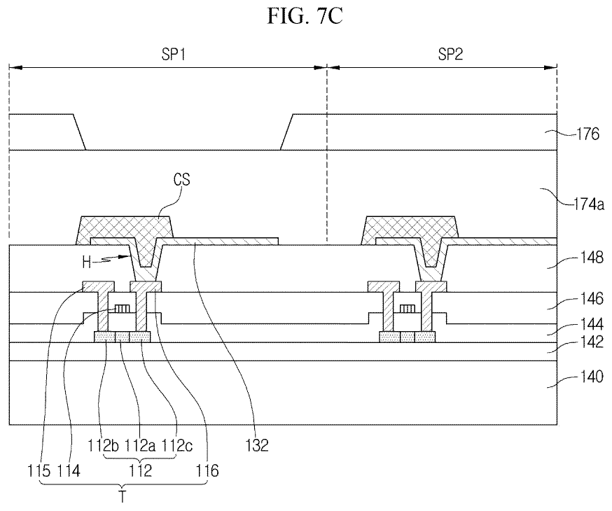

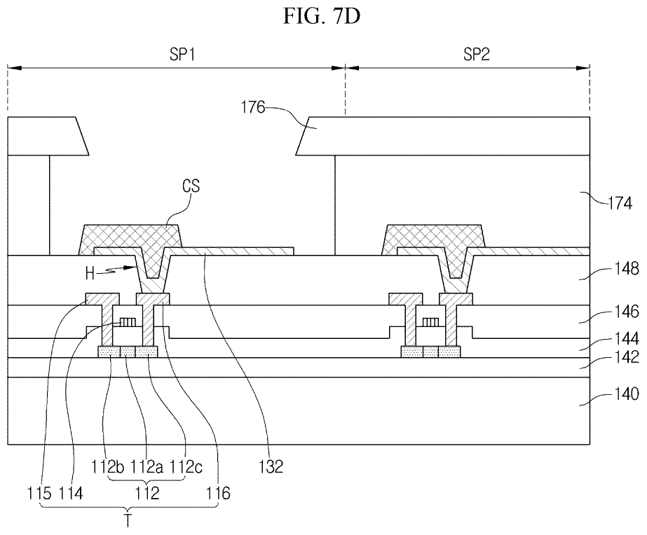

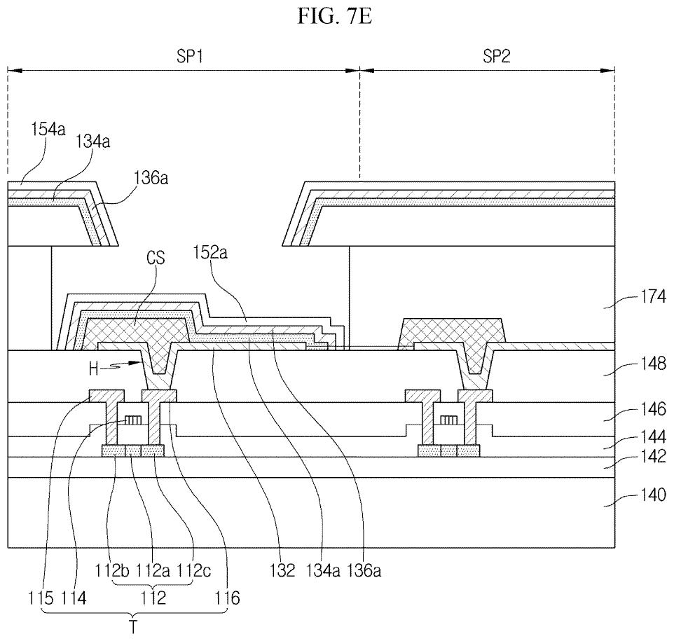

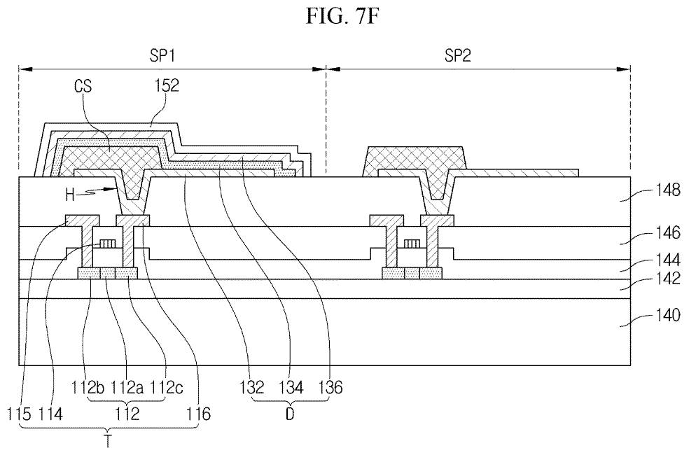

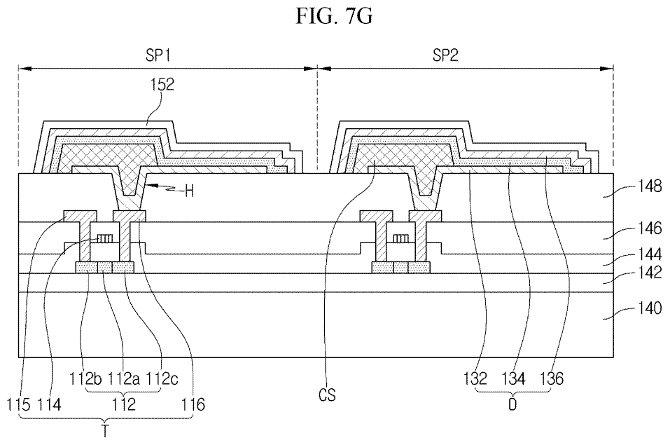

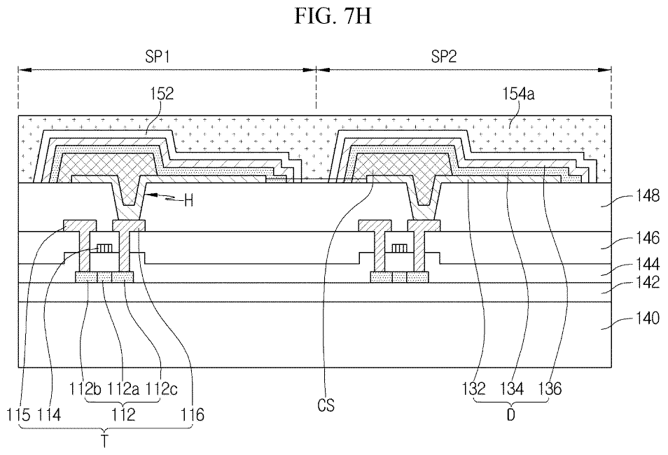

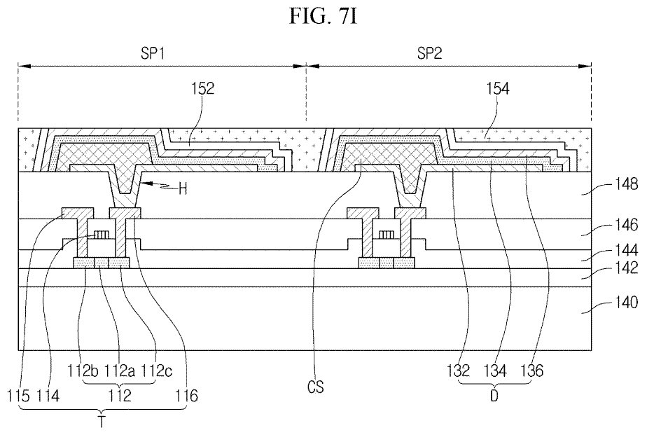

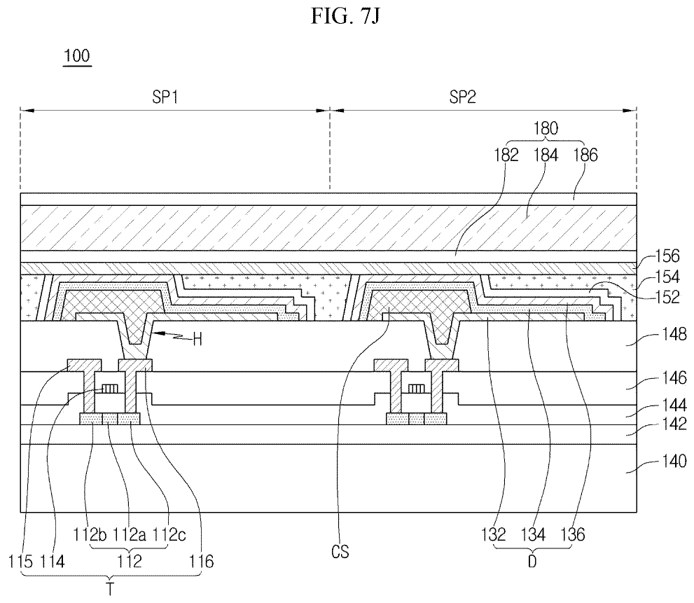

FIGS. 7A to 7J are views showing the method of manufacturing the display apparatus 100 according to the first embodiment of the present disclosure.

First, as shown in FIG. 7A, the buffer layer 142 is formed over the entire substrate 140 including a plurality of sub-pixels SP1 and SP2.

The substrate 140 may be made of the hard material such as the glass or the plastic material such as the plastic material may include a polyimide, a polymethylmethacrylate, a polyethylene tereththalate, a Polyethersulfone, and a Polycarbonate.

The buffer layer 142 may be formed of the single layer of SiNx or SiOx, or multiple layers thereof.

Thereafter, the poly-crystalline semiconductor material such as poly-silicon or the oxide semiconductor material such as etching IGZO (Indium-gallium-zinc-oxide), IZO (Indium-zinc-oxide), IGTO (Indium-gallium-tin-oxide), and IGO (Indium-gallium-oxide) is deposed and etched to form the semiconductor layer 112 in each of the first and second sub-pixels SP1 and SP2 on the buffer layer 142. Further, the impurities are doped into both sides of the semiconductor layer 112 to form the channel region 112a, the source region 112b, and the drain region 112c.

Subsequently, the gate insulating layer is formed 144 by depositing the inorganic material such as SiOx or SiNx, and then the metal such as molybdenum (Mo), aluminum (Al), chromium (Cr), gold (Au), titanium (Ti), nickel (Ni), Neodymium (Nd) and copper (Cu) are deposited by the sputtering method and etched by the wet etching method to form the gate electrode 114. Thereafter, the organic material such as photo acrylic material or the inorganic material such as SiNx or SiOx is deposited on the gate electrode 114 to form the interlayer insulating layer 146, and then the interlayer insulating layer 146 over the source region 112b and the drain region 112c of the semiconductor layer 112 is dry-etched to form the contact holes therein.

Subsequently, the metal such as Cr, Mo, Ta, Cu, Ti, Al, or an Al alloy is deposited by the sputtering method and etched to form the source electrode 115 and the drain electrode 116 which are respectively ohmic-contacted to the source region 112b and the drain region 112c of the semiconductor layer 112 through the contact holes in each of the first and second sub-pixels SP1 and SP2.

Thereafter, the planarization layer 148 is formed by depositing the organic material such as photo-acryl on the source electrode 115 and the drain electrode 116, and then the planarization layer 148 on the drain electrode 116 is dry-etched to form the contact hole.

Subsequently, as shown in FIG. 7B, at least one material of the inorganic insulating material such as SiNx or SiOx, the organic insulating material such as BCB (BenzoCycloButene), an acrylic resin, an epoxy resin, a phenolic resin, a polyamide resin, and a polyimide resin, and a photosensitive agent including a black pigment is deposited over the entire substrate 140 and etched using a dry etching method to form the step prevention member CS.

Thereafter, as shown in FIG. 7C, a first pattern layer 174a is formed, and a photoresist is deposited and patterned thereon to form a second pattern 176.

The first pattern layer 174a may be made of a material having orthogonality. Orthogonality means that any two elements in a set have independent properties. The orthogonality means that different configurations formed inside the display apparatus 100 have different properties. For example, since a specific layer inside the display apparatus 100 has completely different properties from other layers, the materials with orthogonality have little effect on other materials. Further, the orthogonality can be understood as a characteristic in which two objects exist independently, regardless of each other. For example, the material having orthogonality can be both hydrophobicity which has a low affinity for water and oleophobicity which has a low affinity for oil. In the present disclosure, as the orthogonal material, a fluoropolymer material containing a large amount of fluorine (F) in the functional while carbon-carbon bonds are formed continuously in a chain structure can be used, but is not limited thereto.

Thereafter, as shown in FIG. 7D, the second pattern 176 is used as a mask layer to etch the first pattern layer 174a to form the first pattern 174. At this time, a part of the first pattern layer 174a under the second pattern 176 is etched so that the upper second pattern 176 and the lower first pattern 174 form an undercut shape.

Subsequently, an organic light emitting material is deposited in the entire area of the substrate 140 to form the organic pattern 134a on the side and upper surfaces of the step prevention member CS of the first sub-pixel SP1, the upper surface of the first electrode 132 outside the step prevention member CS, and on the first pattern 174, as shown in FIG. 7E.

Subsequently, a metal or transparent metal oxide is deposited in the entire area of the substrate 140 to form a conductive layer 136a on the side and upper surfaces of the step prevention member CS of the first sub-pixel SP1, the upper surface of the first electrode 132 outside the step prevention member CS, and on the first pattern 174. Thereafter, the inorganic material and/or the organic material is deposited in the entire area of the substrate 140 to form the protective pattern 152a on the side and upper surfaces of the step prevention member CS of the first sub-pixel SP1, the upper surface of the first electrode 132 outside the step prevention member CS, and on the first pattern 174.

Thereafter, as shown in FIG. 7F, when the first pattern 174 is removed by the lift-off method, the second pattern 176 on the upper side of the first pattern 174 and the light emitting layer 134a, the conductive layer 136a, and the protective pattern 154a over the second pattern 176 are also removed, so that the light emitting layer 134 and the second electrode 136 are formed in the first sub-pixel SP1 to complete the light emitting device D, and the protective layer 152 is formed thereon.

The protective layer 152 is disposed over the light emitting device D to block the outer impact to the light emitting device D when the first pattern 174 is lifted off, thereby preventing defects in the light emitting device D.

Subsequently, by repeating the processes of FIGS. 7C to 7F, the light emitting device D is formed in the second sub-pixel SP2, as shown in FIG. 7G. Through this process, for example, the light emitting device D can be formed in all of a plurality of R, G, and B sub-pixels.

Thereafter, as shown in FIG. 7H, the organic material such as photoacrylic is deposited over the entire area of the substrate 140 to form the organic layer 154a that covers the light emitting device D of the sub-pixel SP1 and SP2.

Subsequently, as shown in FIG. 71, the organic layer 154a is etched to a set thickness. At this time, the protective layer 152 over the step prevention member CS is also etched together with the organic layer 154a, so that the second planarization layer 154 having the same level as the second electrode 136 over the step prevention member CS is formed in the entire area of the substrate 140.

At this time, a part of the second electrode 136 of the light emitting device D in the sub-pixel SP1 and SP2 (i.e., the second electrode (136) disposed over the step prevention member CS) is exposed to the outside through the surface of the second planarization layer 154.

Thereafter, as illustrated in FIG. 7J, the transparent metal oxide such as ITO or IZO is deposited on the upper surface of the second planarization layer 154 and the upper surface of the protective layer 152 exposed to the outside to form a connecting electrode 156, thereby electrically connecting the light emitting devices D disposed in each of the electrically separated sub-pixels SP1 and SP2.

Subsequently, the inorganic material is applied over the entire area of substrate 140 to form the first encapsulation layer 382, and the organic material is applied on the first encapsulation layer 382 to form the second encapsulation layer 384. Thereafter, the inorganic material is applied on the second encapsulation layer 384 to form the third encapsulation layer 386, thereby forming the encapsulation layer 380 to seal the display apparatus 300.

As described above, in the present disclosure, the first pattern made of the orthogonal material and the second pattern made of the photoresist are formed, and the organic material, the conductive layer, and the inorganic material are deposited thereon, and then the first pattern, the second pattern, and the organic material, the conductive layer, and the inorganic material on the second pattern are removed by the lift-off method, thereby forming the light emitting layer 134, the second electrode 136, and the protective layer 152 in the sub-pixel.

In addition, due to the characteristics of orthogonal materials, the damage to the lower layer can be prevented compared to the process of directly etching the organic layer by the photo process.

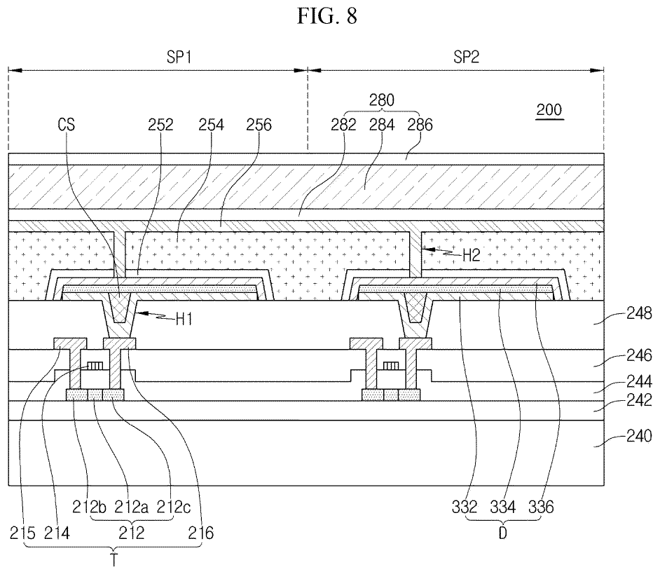

FIG. 8 is the cross-sectional view showing the structure of the display apparatus 200 according to the second embodiment of the present disclosure. At this time, the description of the same structure as the first embodiment of FIG. 6 will be omitted or simplified, and only the different structures will be described in detail.

As shown in FIG. 8, in the display apparatus 200 according to the second embodiment of the present disclosure, the thin film transistor T and the light emitting device D are disposed in each of the sub-pixels SP1 and SP2.

The thin film transistor T includes the semiconductor layer 212 disposed on the buffer layer 242, the gate electrode 214 disposed on the gate insulating layer 244, the source electrode 215 and the drain electrode 216 disposed on the interlayer insulating layer 246.

The first planarization layer 248 is formed over the thin film transistor T, and the light emitting device D is disposed on the first planarization layer 248. The light emitting device D includes the first electrode 232, the light emitting layer 234, and the second electrode 236. At this time, the first electrode 232 may be the anode electrode and the second electrode 236 may be the cathode electrode.

The first electrode 232 of the light emitting device D is electrically connected to the drain electrode 216 of the thin film transistor T through the first contact hole H formed in the first planarization layer 248, so that the signal supplied from the outside is applied to the light emitting device D through the thin film transistor T.

At this time, the step prevention member CS may be disposed inside the first contact hole H where the second electrode 236 is formed. Since the inside of the first contact hole H is filled with the step prevention member CS, the step caused by the second contact hole H can be removed, and as a result, the damage of the light emitting layer 234 caused by the step can be prevented.

Since the step prevention member CS is formed to prevent steps, it can be formed to any thickness as long as it can prevent steps. For example, the step prevention member CS can be formed at the same level as the first electrode 232, but is not limited thereto.

The step prevention member CS can be made of at least one material selected from the group consisting of the inorganic insulating material such as SiNx or SiOx, the organic insulating material such as a BCB (BenzoCycloButene), an acrylic resin, an epoxy resin, a phenolic resin, a polyamide resin, and a polyimide resin, and a photosensitive agent including a black pigment, but is not limited thereto.

The first electrode 232 is disposed in each of the sub-pixels SP1 and SP2. The first electrode 232 may be formed of at least one of silver (Ag), aluminum (Al), gold (Au), molybdenum (Mo), tungsten (W), chromium (Cr), and the alloy thereof, and may also be formed of the transparent metal oxide layer such as ITO or IZO.

The second electrode 236 is disposed in each of the sub-pixels SP1 and SP2. The second electrode 236 is made of the half-transparent alloys such as LiF/Al, CsF/Al, Mg: Ag, Ca/Ag, Ca:Ag, LiF/Mg:Ag, LiF/Ca/Ag, and LiF/Ca:Ag, and the metal such as (Ag), aluminum (Al), gold (Au), molybdenum (Mo), tungsten (W), and chromium (Cr). Further, the second electrode 236 may be made of the transparent metal oxide that transmits light, such as ITO or IZO.

The protective layer 252 may be formed on the second electrode 236 to surround the second electrode 236. The protective layer 252 may be formed of the single layer of the inorganic material such as SiOx or SiNx, but is not limited thereto.

On the protective layer 252, the second planarization layer 254 is formed over the entire area of the display apparatus 200. The second planarization layer 254 may be formed of the organic material such as photoacrylic, but is not limited thereto and may be formed of the multiple layers including the inorganic layers and the organic layers.

The second contact hole H2 is formed in the protective layer 252 on the second electrode 236 of the sub-pixel SP1 and SP2 and the second planarization layer 254, and the connecting electrode 256 is formed in the entire area on the second planarization layer 254. The connecting electrode 256 is electrically connected to the second electrode 236 disposed in each sub-pixel SP1 and SP2 through the second contact hole H2 formed in each sub-pixel SP1 and SP2, thereby electrically connecting the second electrodes 236 disposed in all the sub-pixels of the entire display apparatus 200.

The connecting electrode 256 is formed of the transparent metal oxide such as ITO or IZO, but is not limited thereto.

The capsulation layer 280 including the first capsulation layer 282 made of the inorganic material, the second capsulation layer 284 made of the organic material, and the third capsulation layer 236 made of the inorganic material is disposed on the connecting electrode 256.

In the display apparatus 100 according to the first embodiment shown in FIG. 6, the step prevention member CS is formed not only in the inside of the contact hole H but also on a part of the first planarization layer 148. On the other hand, in the display apparatus 200 of this embodiment, the step prevention member CS is formed only in the inside of the first contact hole H1. Therefore, in the display apparatus 200 according to this embodiment, the defect of the light emitting device D due to the step can be prevented more effectively.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate;
a plurality of sub-pixels on the substrate;
a transistor disposed in each sub-pixel;
a first planarization layer disposed in an entire area of the substrate and covers the transistor;
a first contact hole in the first planarization layer;
a light emitting device disposed in each sub-pixel, the light emitting device being electrically connected to the transistor through the first contact hole in the first planarization layer; and
a step prevention member disposed in a selected region including the first contact hole in each sub-pixel.

2. The display apparatus of claim 1, wherein the step prevention member is extended to an upper surface of the first planarization layer from an inside of the first contact hole.

3. The display apparatus of claim 2, wherein the light emitting device including:
a first electrode disposed on the first planarization layer and in the inside of the first contact hole in each sub-pixel;
a light emitting layer disposed in side and upper surfaces of the step prevention layer and on the upper surface of the first electrode; and
a second electrode disposed on the light emitting layer.

4. The display apparatus of claim 1, wherein the step prevention member is present only within the inside of the first contact hole.

5. The display apparatus of claim 2, wherein the light emitting device including:
a first electrode disposed on the first planarization layer and in the inside of the first contact hole in each sub-pixel;
a light emitting layer disposed on the upper surface of the step prevention layer and on the upper surface of the first electrode; and
a second electrode disposed on the light emitting layer.

6. The display apparatus of claim 5, wherein the light emitting layer disposed on the upper surface of the step prevention member and the light emitting layer disposed on the upper surface of the first electrode are at a same level.

7. The display apparatus of claim 1, wherein the step prevention member is disposed in a region where the transistor is formed.

8. The display apparatus of claim 1, wherein the step prevention member is disposed in a boundary region of the plurality of sub-pixels.

9. The display apparatus of claim 1, wherein the step prevention member is made of at least one material selected from a group consisting of an inorganic insulating material, an organic insulating material, and a photosensitive agent having a black pigment.

10. The display apparatus of claim 1, further comprising:
a protective layer on the upper surface of the second electrode disposed in each sub-pixel;
a second planarization layer formed in an entire area of the substrate; and
a connecting electrode electrically connected to the second electrodes of the plurality of light emitting devices on the second planarization layer.

11. The display apparatus of claim 10, wherein the second planarization layer is disposed at a same level as the second electrode to expose the second electrode to the outside on the surface of the second planarization layer, and
wherein the connecting electrode is electrically connected to the exposed second electrode.

12. The display apparatus of claim 10, wherein the second electrode is covered with the second planarization layer having a second contact hole thereon, and
wherein the connecting electrode is electrically connected to the second electrode through the second contact hole.

13. The display apparatus of claim 10, further comprising an encapsulating layer over the connecting electrode.

14. A method of fabricating a display apparatus, comprising:
providing a substrate including a plurality of sub-pixels;
forming a transistor in each sub-pixels;
forming a first planarization layer in an entire area of the substrate and etching the first planarization layer over the transistor to form a first contact hole;
forming a first electrode in an inside of the first contact hole in each sub-pixel and on the first planarization layer;
forming a step prevention member in a selected portion including the first contact hole;
depositing a material having orthogonality and a photo resist in the entire area of the substrate;
developing the photo resist to form a second pattern;
over-etching the material having orthogonality using the second pattern to form a first pattern to form an undercut shape with the second pattern;
depositing a light emitting material and a conductive material using the first pattern and the second pattern in the undercut shape as a mask layer to form a light emitting layer and a second electrode; and
removing the first pattern and the second pattern by a lift-off process.

15. The method of claim 14, further comprising:
forming a protective layer over the second electrode using the first pattern and the second pattern in the undercut shape as the mask layer;
forming a second planarization layer in an entire area of the substrate; and
forming a connecting electrode electrically connected to the light emitting device on the second planarization layer.

16. The method of claim 15, further comprising exposing the second electrode to outside through the surface of the second planarization layer by etching the entire area of second planarization layer in selected thickness, and
wherein the connecting electrode is electrically connected to the exposed upper surface of the second electrode.

17. The method of claim 15, further comprising forming a second contact hole by etching the second planarization layer over the second electrode, and
wherein the connecting electrode is electrically connected to the second electrode through the second contact hole.
